(19) United States
(12) Patent Application Publication
(10) Pub. No.: US 2019/0361057 A1
(43) Pub. Date: Nov. 28, 2019

(54) CURRENT DETECTOR

(71) Applicant: SANYO Electric Co., Ltd., Daito-shi, Osaka (JP)

(72) Inventors: Shinya Nakano, Hyogo (JP); Tomonori Kunimitsu, Hyogo (JP); Katsutoshi Koyama, Hyogo (JP)

(73) Assignee: SANYO Electric Co., Ltd., Daito-shi, Osaka (JP)

(21) Appl. No.: 16/486,564

(22) PCT Filed: Mar. 15, 2018
(86) PCT No.: PCT/JP2018/010115

§ 371 Date: Aug. 16, 2019

(30) Foreign Application Priority Data
Mar. 17, 2017 (JP) 2017-053065

(51) Int. Cl. G01R 19/32; G01R 31/3842

(52) U.S. Cl. CPC G01R 19/32; G01R 31/3842

(57) ABSTRACT

A current detector includes a temperature sensor that detects a temperature that corrects variation in electric resistance of a shunt resistor caused by a temperature of the shunt resistor. The shunt resistor detects electric current. The temperature sensor includes a thermocouple. The thermocouple includes a pair of temperature detecting leads made of different types of metals, respectively. The pair of temperature detecting leads are connected to each other at a measurement point at front ends of the pair of temperature detecting leads. A measurement point of the thermocouple is electrically connected to the shunt resistor.

### TECHNICAL FIELD

The present invention mainly relates to a current detector that detects large electric current, and relates particularly to a current detector that is most suitable to detect electric current that charges or discharges a battery for traveling that supplies electric power to a motor for traveling of a vehicle.

### BACKGROUND ART

A battery is used as a power source that is attached to a hybrid vehicle or an electric vehicle and supplies electric power to a motor for traveling. It is particularly important to accurately detect electric current, and accurately calculate a remaining capacity of the battery, based on values of detected electric current. The reason is that the battery is protected by controlling electric current that charges or discharges the battery, and thus maintaining the remaining capacity of the battery within a predetermined range. If the remaining capacity is not accurately detected, the fact that the battery is over-charged or over-discharged is not accurately detected. Consequently, the battery substantially deteriorates, and sufficient safety is not secured. Since the remaining capacity of the battery is calculated by adding up electric current that charges or discharges the battery, electric current needs to be accurately detected. Electric current of the battery is calculated, based on voltage drop across a shunt resistor connected to the battery in series. The reason is that the voltage drop across the shunt resistor increases in proportion to a product of electric resistance and electric current of the shunt resistor.

Since a temperature of the shunt resistor varies electric resistance of the shunt resistor, electric current is accurately detected by detecting a temperature of the shunt resistor and correcting electric resistance, based on the detected temperature. To accurately detect electric current, a current detector has been developed that includes a temperature sensor thermally coupled to the shunt resistor (see PTL 1).

### CITATION LIST

### Patent Literature

PTL 1: Unexamined Japanese Patent Publication No. 2013-174555

### SUMMARY OF THE INVENTION

### Technical Problem

A conventional current detector that detects a temperature of a shunt resistor includes a temperature sensor. The temperature sensor is thermally coupled to a resistor portion of the shunt resistor. An insulation sheet is between the temperature sensor and the resistor portion. The resistor portion is at a central portion of the shunt resistor. In the current detector that has the configuration, thermal energy of the shunt resistor is transferred to the temperature sensor through the insulation sheet. Therefore, detection of a temperature of the shunt resistor delays. If a temperature sensor does not promptly detect variation in temperatures of the shunt resistor, the temperature sensor does not accurately correct variation in electric resistance of the shunt resistor. Especially if electric current significantly varies and temperatures of the shunt resistor significantly vary, electric resistance is not accurately corrected based on the temperatures. Since an error in electric resistance of the shunt resistor becomes an error in a value of detected electric current, a delay in a detected temperature decreases accuracy of a value of detected electric current.

The present invention is developed to solve a conventional disadvantage described above. An important object of the present invention is to provide a current detector that very accurately detects electric current by means of a shunt resistor.

### Solutions to Problem and Advantageous Effects of Invention

A current detector according to an aspect of the present invention includes a shunt resistor, and a temperature sensor that detects a temperature that corrects variation in electric resistance of the shunt resistor caused by a temperature of the shunt resistor. The temperature sensor includes a pair of temperature detecting leads that form a thermocouple. A measurement point at front ends of the pair of temperature detecting leads is electrically and thermally connected to the shunt resistor, and is fixed to the shunt resistor.

The current detector described above very accuracy detects electric current by means of the shunt resistor. Electric current that sharply varies is especially promptly and very accurately detected by the current detector described above. The reason is that the current detector described above detects a temperature of the shunt resistor by means of the thermocouple that has a small heat capacity. The shunt resistor is a resistor that detects electric current. Another reason is that an insulation sheet is not between the measurement point of the thermocouple and the shunt resistor, and thus the measurement point of the thermocouple is electrically connected to and thermally coupled to the shunt resistor. The thermocouple includes the pair of temperature detecting leads made of different types of metals, respectively. The pair of temperature detecting leads are electrically connected to each other at the measurement point at front ends of the pair of temperature detecting leads. Since the measurement point is made of metal, the measurement point is surely and electrically connected to a surface of the shunt resistor made of metal, using methods, such as welding. Since the thermocouple is electrically and directly connected to a surface of the shunt resistor, thermal resistance and a heat capacity between the measurement point and the shunt resistor are very small. Therefore, the thermocouple promptly transfers a temperature of the shunt resistor to the measurement point. Therefore, the thermocouple very accurately detects temperatures of the shunt resistor that vary.

FIG. 3 illustrates temperatures of the shunt resistor that vary due to electric current that flows through the shunt resistor. In FIG. 3, curve A represents variation in electric current, curve B represents characteristic detection of temperatures by a temperature detector according to an aspect of the present invention, and curve C represents temperatures detected by a thermistor disposed at the shunt resistor. Then, an insulation sheet is between the thermistor and the shunt resistor. As illustrated in FIG. 3, while temperatures of the shunt resistor sharply vary because electric current significantly varies, the temperature detector according to an aspect of the present invention promptly and accurately detects the varying temperatures without time delay from the thermistor. The reason is that an insulation sheet is not between a measurement point at front ends and the shunt resistor, and thus the measurement point is electrically and directly connected to the shunt resistor. Therefore, thermal resistance and a heat capacity between the measurement point and the shunt resistor are very small, and the measurement point is thermally coupled to a surface of the shunt resistor. Therefore, since a rise in temperature of the shunt resistor increases electric resistance of the shunt resistor, the temperature detector according to an aspect of the present invention always accurately corrects electric resistance of the shunt resistor whose temperatures vary. Therefore, the temperature detector according to an aspect of the present invention very accurately detects a value of electric current.

The current detector according to an aspect of the present invention may further include a lead that detects voltage drop across the shunt resistor. The pair of temperature detecting leads are fixed to one end of the shunt resistor, and the lead is fixed to the other end of the shunt resistor, and one of the pair of temperature detecting leads and the lead constitute a pair of voltage detecting leads that detect voltage drop across the shunt resistor. According to the configuration, one of the temperature detecting leads also functions as the voltage detecting lead. Therefore, it is easy to wire the shunt resistor to a temperature detecting circuit and a current detecting circuit. The temperature detecting circuit and the current detecting circuit are almost unexceptionally included in a circuit board. Therefore, the current detector reduces leads that connect the shunt resistor to the circuit board, and allows the shunt resistor to be easily wired to the circuit board.

In the current detector according to an aspect of the present invention, the shunt resistor may include terminal portions at both ends of the shunt resistor, and a resistor portion between the terminal portions, and the measurement point of the thermocouple may be connected to one of the terminal portions of the shunt resistor, and one of the voltage detecting leads may be connected to the other terminal portion of the shunt resistor. Further, in the current detector according to an aspect of the present invention, one of the temperature detecting leads and the voltage detecting leads may be made of copper.

The current detector described above accurately detects voltage drop across the resistor portion, and allows the shunt resistor to be easily wired to the temperature detecting circuit and the current detecting circuit. The reason is that the current detecting circuit is allowed to detect voltage across both ends of the resistor portion by connecting the measurement point of the thermocouple to the terminal portion.

In the current detector according to an aspect of the present invention, the measurement point of the thermocouple may be electrically connected to the shunt resistor by welding, or pressure welding, or with rivet connection, electrically conductive adhesive, or a screw.

In the current detector according to an aspect of the present invention, the shunt resistor may be connected in series to a battery for traveling that supplies electric power to a motor for traveling of a vehicle, and may function as an element that detects electric current that charges or discharges the battery for traveling. The current detector accurately detects electric current of the battery for traveling, and accurately calculates a remaining capacity. The current detector detects electric current that charges or discharges the battery. The remaining capacity is calculated by adding up values of electric current that have been detected. Electric current that charges or discharges the battery is controlled to maintain the remaining capacity within a predetermined range. Consequently, the battery for traveling of a vehicle is not allowed to be overcharged or over-discharged. It is very important for the application to accurately detect electric current of the battery. If there are errors in detection of electric current, a predetermined range of the remaining capacity needs to be narrowed not to allow the battery to be over-charged or over-discharged. The battery is allowed to be charged or discharged within the predetermined range of the remaining capacity. If errors in detection of electric current increase, a capacity of the battery within which the battery is actually charged or discharged is narrowed accordingly. If electric current is accurately detected, the predetermined range of the remaining capacity within which the battery is allowed to be charged or discharged is widened. Therefore, a capacity of the battery within which the battery is actually charged or discharged increases. Therefore, the battery is not allowed to be overcharged or over-discharged, and a capacity of the battery within which the battery is allowed to be charged or discharged increases.

The current detector according to an aspect of the present invention may further include the current detecting circuit that detects voltage drop across the shunt resistor, and calculates a value of electric current that flows through the shunt resistor, and the current detecting circuit may use a temperature detected by the temperature sensor to correct electric resistance of the shunt resistor, and may calculate a value of electric current, based on voltage drop that generates across both ends of the shunt resistor.

### BRIEF DESCRIPTION OF DRAWINGS

FIG. 1 is a block diagram that illustrates an example of a current detector of the present invention.

FIG. 2 is a block diagram that illustrates another example of the current detector of the present invention.

FIG. 3 is a graph that represents characteristic detection of temperatures of a shunt resistor by the current detector of the present invention, and characteristic detection of temperatures of the shunt resistor by a conventional temperature sensor.

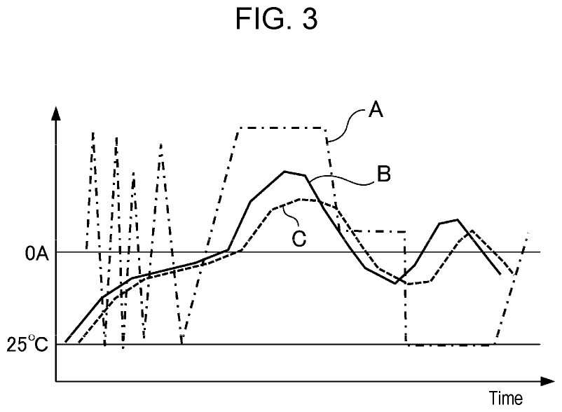

### DESCRIPTION OF EMBODIMENT

Hereinafter, an exemplary embodiment of the present invention will be described with reference to the drawings. However, the exemplary embodiment described later exemplifies a current detector that embodies a technical idea of the present invention. The present invention is not limited to the current detector described later.

In the present description, to facilitate understanding the claims, reference marks that correspond to components described in the exemplary embodiment are assigned to components recited in “Claims” and “Solutions to problem and advantageous effects of invention”. However, the components recited in the claims are not limited to the components described in the exemplary embodiment.

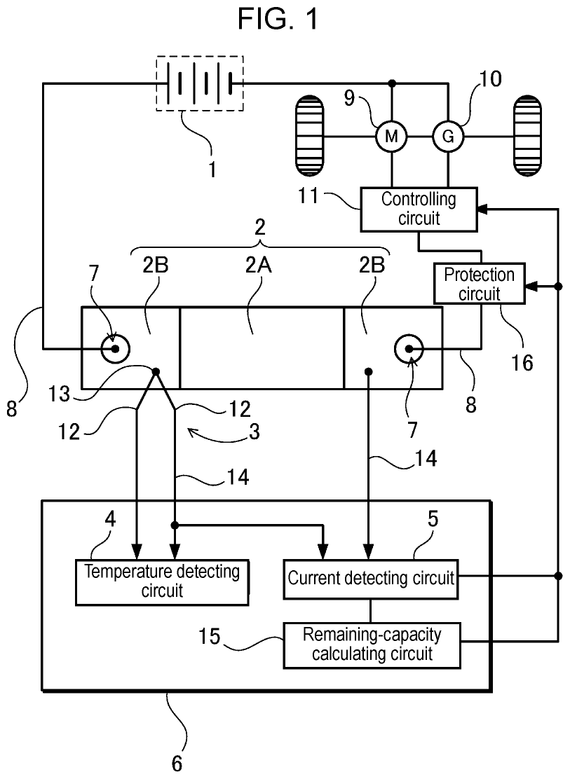

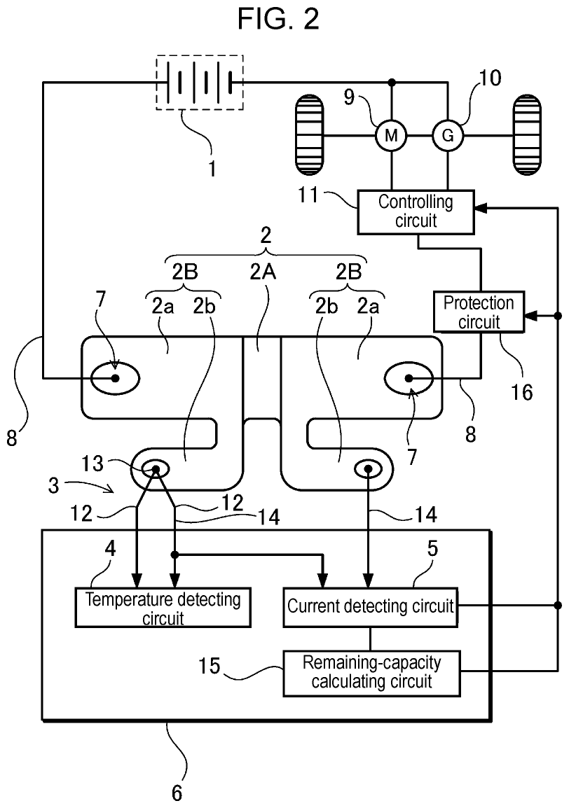

FIGS. 1 and 2 each illustrate a current detector attached to a vehicle. The current detector detects electric current that charges or discharges battery 1 for traveling. The current detector includes shunt resistor 2 connected to battery 1 in series, temperature sensor 3 that detects a correction temperature that corrects variation in electric resistance of shunt resistor 2 caused by a temperature of shunt resistor 2, and temperature detecting circuit 4. Temperature detecting circuit 4 is connected to temperature sensor 3. Signals are input from temperature sensor 3 into temperature detecting circuit 4. Temperature detecting circuit 4 calculates temperatures, based on the input signals. The current detector in FIG. 1 or 2 also includes current detecting circuit 5 that detects voltage drop across shunt resistor 2 to calculate a value of electric current, based on the detected voltage. Circuit board 6 includes temperature detecting circuit 4 and current detecting circuit 5.

Shunt resistor 2 includes terminal portions 2B at both ends of shunt resistor 2, and resistor portion 2A between terminal portions 2B. Shunt resistor 2 is a metal sheet in which resistor portion 2A has a conductivity lower than a conductivity of terminal portions 2B. An electric resistance of resistor portion 2A is constant, and thus determines electric resistance of the shunt resistor. Terminal portions 2B have a low resistance, and are connected to both ends of resistor portion 2A, respectively. Shunt resistor 2 is one metal sheet that has an integral structure that includes resistor portion 2A and terminal portions 2B. Metal sheets that become terminal portions 2B, respectively, are connected to both ends of a metal sheet that becomes resistor portion 2A by welding or pressure welding, respectively. Terminal portions 2B include through holes 7 in both surfaces, respectively. Through holes 7 are used for connection. In FIG. 1, shunt resistor 2 includes terminal portions 2B that are connected to lead 8, temperature detecting leads 12, and voltage detecting leads 14. In FIG. 2, shunt resistor 2 includes terminal portions 2B that include first terminal portions 2a connected to lead 8, and second terminal portions 2b connected to temperature detecting leads 12 and voltage detecting leads 14.

Terminal portions 2B of shunt resistor 2 are connected to lead 8. Lead 8 connects shunt resistor 2 to battery 1 in series. Lead 8 also connects battery 1 to motor 9 and generator 10. In case of a hybrid vehicle, shunt resistor 2 and lead 8 connect battery 1 to motor 9 and generator 10. In case of an electric vehicle, shunt resistor 2 and lead 8 connect battery 1 to motor 9 and a battery charger (not illustrated). Motor 9 and generator 10 are connected to battery 1 through controlling circuit 11. While the vehicle is traveling, controlling circuit 11 controls electric current that discharges the battery and flows through motor 9, and controls electric current that is from generator 10 and charges the battery to maintain a remaining capacity of the battery within a predetermined range. FIG. 1 is exemplified as a current sensor used in an electric power source device attached to a vehicle. A shunt resistor is not necessarily disposed as illustrated in a circuit diagram of FIG. 1, but may be disposed at a path where electric current is measured, as necessary. In FIG. 1, the shunt resistor is connected in series to a parallel circuit that includes the motor and the generator, and shunt resistance detects electric current that flows through the motor and the generator. However, the shunt resistor is connected to a path where electric current is measured, and detects electric current that flows a circuit. Therefore, in an electric vehicle, the shunt resistor may be connected to a motor in series to detect electric current through the motor, may be connected to a generator in series to detect electric current from the generator, and may be connected to a negative side or a positive side of a battery to detect electric current that flows into the battery, although the shunt resistors are not illustrated.

Temperature sensor 3 is a thermocouple that includes a pair of temperature detecting leads 12. The pair of temperature detecting leads 12 are thin and made of different types of metals, respectively. The pair of temperature detecting leads 12 are connected to each other at measurement point 13 at front ends of the pair of temperature detecting leads 12. The thermocouple is temperature sensor 3 that is based on the Seebeck effect and detects a temperature. The thermocouple includes the pair of temperature detecting leads 12 made of different types of metals, respectively. The pair of temperature detecting leads 12 are electrically connected to each other at measurement point 13 at front ends of the pair of temperature detecting leads 12. Rear ends of the pair of temperature detecting leads 12 are open. The thermocouple detects a temperature by detecting a potential difference caused by thermoelectromotive force. If rear ends of the pair of temperature detecting leads are open, the thermocouple detects open-circuit voltage. Alternatively, if the temperature detecting leads are connected, electric current that flows through a closed loop is detected to detect a temperature of the measurement point. Types of thermocouples as temperature sensors are classified according to types of the different types of metals in Japanese Industrial Standards (JIS). A thermocouple of type (T) in JIS includes a positive lead made of copper and a negative lead made of an alloy (constantan) mainly made of copper and nickel. The thermocouple includes the positive lead made of copper, and thus is most suitable to also function as a lead for detection of voltage. However, the present invention is not limited to a thermocouple of type (T) in JIS, but types J, K in JIS are also used, for example.

The thermocouple as the temperature sensor includes measurement point 13 electrically connected to terminal portion 2B of shunt resistor 2. One of temperature detecting leads 12 also functions as voltage detecting lead 14. Temperature detecting lead 12 that is made of copper and is a positive lead also functions as voltage detecting lead 14. Therefore, the thermocouple accurately detects voltage of shunt resistor 2. The reason is that both voltage detecting leads 14 are connected to both ends of shunt resistor 2, respectively. If a measurement point is connected to a center of the resistor portion, the thermocouple more accurately detects a temperature. The reason is that a temperature of the shunt resistor is highest at a center of the shunt resistor. To dispose the measurement point close to a central portion of the shunt resistor, measurement point 13 of the thermocouple in FIG. 1 is connected to a portion of terminal portion 2B close to a boundary between terminal portion 2B and resistor portion 2A. If measurement point 13 is connected to the position, the thermocouple accurately detects a temperature of shunt resistor 2, and also accurately detects voltage by means of temperature detecting lead 12 that also functions as voltage detecting lead 14.

A temperature of the shunt resistor is highest at a central portion of the shunt resistor since terminal portions at both ends of the shunt resistor release heat into leads connected to the terminal portions. If a position where the measurement point is connected is closer to a central portion of the shunt resistor, the thermocouple more accurately detects a temperature of the shunt resistor. However, if the measurement point of the thermocouple is connected to the resistor portion, the thermocouple does not accurately detect voltage across the shunt resistor by means of the temperature detecting lead that also functions as the voltage detecting lead. Therefore, preferably, the measurement point of the thermocouple is connected to a section of a terminal portion close to the resistor portion. Electric resistance of the terminal portion is relatively lower than electric resistance of the resistor portion. Therefore, even if the measurement point is disposed at any position in the terminal portion, voltage that generates across both ends of the shunt resistor is not significantly less accurately detected. However, the measurement point of the thermocouple may be disposed at an end of the resistor portion close to the terminal portion, and the temperature detecting lead may also function as the voltage detecting lead. The reason is that the closer to the end of the resistor portion, the smaller a difference between a voltage of the resistor portion and a voltage of the terminal portion.

Ideally, measurement point 13 of the thermocouple is electrically connected to shunt resistor 2 by welding. However, measurement point 13 is electrically connected to shunt resistor 2 not only by welding but also by other methods. Instead of welding, measurement point 13 is electrically connected to shunt resistor 2 by pressure welding, or with rivet connection, electrically conductive adhesive, or screws, for example. Measurement point 13 of the thermocouple is formed by connecting front ends of the pair of temperature detecting leads 12 to each other, and measurement point 13 is connected to shunt resistor 2. Alternatively, front ends of temperature detecting leads 12 may be connected to shunt resistor 2, and may also be disposed close to each other. Consequently, temperature detecting leads 12 may be connected to each other by means of shunt resistor 2 to form measurement point 13.

Temperature detecting circuit 4 calculates a temperature of measurement point 13 based on thermoelectromotive force between open ends of the thermocouple that is the temperature sensor. The reason is that a type and a temperature of the thermocouple determine the thermoelectromotive force between open ends. Temperatures at both ends of temperature detecting leads 12 determine thermoelectromotive force of the thermocouple. Therefore, temperature detecting circuit 4 includes a circuit that detects a temperature of open ends of the thermocouple. The temperature of open ends of the thermocouple is used as a reference temperature. The reference temperature is detected by a thermistor or a thermocouple (not illustrated) incorporated within the temperature detecting circuit since electric current does not vary a temperature of the temperature detecting circuit, unlike a temperature of the shunt resistor. Instead of the thermistor or the thermocouple incorporated within the temperature detecting circuit, the reference temperature is detected by utilizing voltage between a base and an emitter of a transistor that varies by temperature, or forward voltage of a diode that varies by temperature. In case of this configuration, no thermistor or no thermocouple needs to be incorporated within the temperature detecting circuit. Temperature detecting circuit 4 calculates a temperature of measurement point 13, based on thermoelectromotive force between open ends of the thermocouple and the reference temperature.

Current detecting circuit 5 calculates electric current that flows through shunt resistor 2, based on voltage that generates across both ends of shunt resistor 2. Current detecting circuit 5 uses a correction temperature of shunt resistor 2 detected by temperature detecting circuit 4 to correct electric resistance of resistor portion 2A. Current detecting circuit 5 detects electric current, based on the corrected electric resistance and voltage drop across both ends of shunt resistor 2. Current detecting circuit 5 includes a memory that stores relations between temperatures of shunt resistor 2 and values of electric resistance in a form of a function of the temperatures or a lookup table. Based on the function or the lookup table stored in the memory, current detecting circuit 5 determines a value of electric resistance, based on a temperature of the shunt resistor. Then current detecting circuit 5 calculates electric current, based on the determined value of electric resistance and a voltage drop that generates across both ends of the shunt resistor. Current detecting circuit 5 uses equation I=E/R to calculate electric current (I) through shunt resistor 2. In equation I=E/R, (R) is a value of electric resistance that has been corrected with a temperature of shunt resistor 2, and (E) is voltage drop that generates across shunt resistor 2.

A value of electric current detected by current detecting circuit 5 is input into remaining-capacity calculating circuit 15 that calculates a remaining capacity of the battery, is input into a protection circuit (not illustrated) that detects overcurrent and interrupts electric current of the battery, and is input into controlling circuit 11 that controls electric current through motor 9 and electric current from generator 10. The current detector in FIG. 1 includes temperature detecting circuit 4, current detecting circuit 5, and remaining-capacity calculating circuit 15 on circuit board 6. If the vehicle stops for a fixed period of time and voltage of battery 1 stabilizes, remaining-capacity calculating circuit 15 may use the voltage of battery 1 that has stabilized to calculate a remaining capacity. However, while the vehicle is traveling, voltage drop is caused by internal resistance and electric current of battery 1, and thus it is difficult for remaining-capacity calculating circuit 15 to calculate a remaining capacity, based on voltage. Therefore, while the vehicle is traveling, remaining-capacity calculating circuit 15 calculates a remaining capacity of the battery by adding up or integrating electric current that charges or discharges the battery. The electric current that charges or discharges the battery is input from the current detecting circuit to remaining-capacity calculating circuit 15. Remaining-capacity calculating circuit 15 calculates the remaining capacity of the battery by adding or integrating electric current that charges the battery to added-up or integrated values and by subtracting electric current that discharges the battery from the added-up or integrated values. If a value of electric current is input from the current detecting circuit to protection circuit 16 and exceeds a maximum electric current that has been predetermined, protection circuit 16 interrupts electric current by means of a protection element (not illustrated), such as a breaker or a fuse, and thus protects the battery. Controlling circuit 11 monitors values of electric current input from the current detecting circuit to controlling circuit 11, and controls electric current through motor 9 and electric current from generator 10.

### INDUSTRIAL APPLICABILITY

A current detector of the present invention is most suitable to accurately detect electric current that significantly varies by means of a shunt resistor. For example, the electric current that significantly varies is electric current that charges or discharges a battery for traveling that is attached to a vehicle.

### REFERENCE MARKS IN THE DRAWINGS

1 battery
2 shunt resistor
2A resistor portion
2B terminal portion
2a first terminal portion
2b second terminal portion
3 temperature sensor (thermocouple)
4 temperature detecting circuit
5 current detecting circuit
6 circuit board
7 through hole
8 lead
9 motor
10 generator
11 controlling circuit
12 temperature detecting lead
13 measurement point
14 voltage detecting lead
15 remaining-capacity calculating circuit
16 protection circuit

1. A current detector comprising:
a shunt resistor; and
a temperature sensor that detects a correction temperature that corrects variation in electric resistance of the shunt resistor caused by a temperature of the shunt resistor,
wherein the temperature sensor includes a pair of temperature detecting leads that form a thermocouple, and a measurement point at front ends of the pair of temperature detecting leads is electrically and thermally connected to the shunt resistor, and is fixed to the shunt resistor.

2. The current detector according to claim 1, further comprising
a lead that detects voltage drop across the shunt resistor,
wherein the pair of temperature detecting leads are fixed to one end of the shunt resistor, and the lead is fixed to the other end of the shunt resistor, and
one of the pair of temperature detecting leads and the lead constitute a pair of voltage detecting leads that detect voltage drop across the shunt resistor.

3. The current detector according to claim 2, wherein
the shunt resistor includes terminal portions at both ends of the shunt resistor, and a resistor portion between the terminal portions, and
the measurement point of the thermocouple is connected to one of the terminal portions of the shunt resistor, and one of the voltage detecting leads is connected to the other terminal portion of the shunt resistor.

4. The current detector according to claim 3, wherein
one of the temperature detecting leads and the voltage detecting leads are made of copper.

5. The current detector according to claim 1, wherein
the measurement point of the thermocouple is electrically connected to the shunt resistor by welding, or pressure welding, or with rivet connection, electrically conductive adhesive, or a screw.

6. The current detector according to claim 1, wherein
the shunt resistor is connected in series to a battery for traveling that supplies electric power to a motor for traveling of a vehicle, and functions as an element that detects electric current that charges or discharges the battery.

7. The current detector according to claim 1, further comprising
a current detecting circuit that detects voltage drop across the shunt resistor, and calculates a value of electric current that flows through the shunt resistor,
wherein the current detecting circuit uses a temperature detected by the temperature sensor to correct electric resistance of the shunt resistor, and calculates a value of electric current, based on voltage drop that generates across both ends of the shunt resistor.
